(19) United States
(12) Patent Application Publication
(10) Pub. No.: US 2025/0275372 A1
(43) Pub. Date: Aug. 28, 2025

(54) DISPLAY DEVICE

(71) Applicant: LG DISPLAY CO., LTD., Seoul (KR)

(72) Inventors: HeeJung YANG, Paju-si (KR); YoungWook LEE, Paju-si (KR); Hoseung LEE, Paju-si (KR); SeungHee NAM, Paju-si (KR)

(73) Assignee: LG DISPLAY CO., LTD., Seoul (KR)

(21) Appl. No.: 18/958,680

(22) Filed: Nov. 25, 2024

(30) Foreign Application Priority Data
Feb. 22, 2024 (KR) 10-2024-0025424

(51) Int. Cl. H10K 59/122; H10K 59/80

(52) U.S. Cl. CPC H10K 59/122; H10K 59/879

(57) ABSTRACT

A display device includes a structure where a first electrode is located in an area other than a depressed portion of an insulating layer and includes at least one trunk portion and at least one branch portion connected to the trunk portion, and thereby, is capable of improving emission efficiency or light extraction efficiency.

### CROSS-REFERENCE TO RELATED APPLICATION

This application claims the priority of Republic of Korea Patent Application No. 10-2024-0025424, filed on Feb. 22, 2024, which is hereby incorporated by reference in its entirety.

### BACKGROUND

### Field of the Disclosure

The present disclosure relates to electronic devices with displays, and more specifically, to display devices.

### Description of the Background

Along with the development of information and communication technology, display devices have become increasingly important for serving to provide various information on a display screen.

To provide various information to users, display devices may be required to have excellent display quality and high luminous efficiency.

In particular, the luminous efficiency is becoming increasingly important because display devices are required to use limited power as multimedia technology advances.

The luminous efficiency of display devices may be depended on the emission efficiency of light emitting elements included in the display devices.

Display devices including light emitting elements with high emission efficiency may have excellent luminous efficiency.

Therefore, to improve the luminous efficiency of display devices, it may be needed to improve the emission efficiency of light emitting elements.

However, there are several obstacles to improve the emission efficiency of light emitting elements.

### SUMMARY

One or more aspects of the present disclosure may provide a display device with a structure capable of improving light extraction efficiency and preventing light leakage.

One or more aspects of the present disclosure may provide a display device that has a structure where one subpixel includes a plurality of light emitting areas emitting light of the same color, and thereby, is capable of being driven with low power based on high luminance characteristics.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a display device includes a substrate on which a plurality of subpixels are disposed, an insulating layer disposed over the substrate and including at least one depressed portion in at least one subpixel among the plurality of subpixels, a first electrode disposed on the insulating layer, disposed in an area other than the at least one depressed portion, and including at least one trunk portion and at least one branch portion connected to the at least one trunk portion, a bank layer disposed on at least a portion of an upper surface of the first electrode and the insulating layer and including an open area in each of the plurality of subpixels, an emission layer disposed in the open area, and a second electrode disposed on the emission layer.

In another aspect of the present disclosure, a display device includes a first non-light emitting area comprising a first groove and a second groove alternately disposed with the first groove in at least part of a display area, a first light emitting area surrounding the first non-light emitting area, a second light emitting area surrounding the first light emitting area, and a second non-light emitting area comprising the second light emitting area.

According to one or more aspects of the present disclosure, a display device may be provided that includes a structure where a depressed portion is disposed in an area corresponding to an open area of a bank layer, and thereby, is capable of improving light extraction efficiency and preventing or reducing light leakage.

According to one or more aspects of the present disclosure, a display device may be provided that has a structure where one subpixel includes a plurality of light emitting areas and a plurality of non-light emitting areas, and thereby, is capable of being driven with low power based on improved luminous efficiency.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure.

In the drawings:

FIG. 1 illustrates an example system configuration of a display device according to aspects of the present disclosure;

FIG. 2 is a plan view of an example area where subpixels are disposed in an active area of a display panel according to aspects of the present disclosure;

FIG. 3 is a plan view of example light emitting areas in the display device according to aspects of the present disclosure;

FIGS. 4A to 4C are enlarged plan views of area A in FIG. 3 according to aspects of the present disclosure;

FIGS. 5A and 5B are example plan views illustrating a light emitting area and a non-light emitting area of FIG. 4A according to aspects of the present disclosure;

FIGS. 6A and 6B are example cross-sectional views taken along line A-B of FIG. 2 according to aspects of the present disclosure;

FIG. 7 is a plan view illustrating an example structure of four subpixels in the display device according to aspects of the present disclosure;

FIG. 8 is an example cross-sectional view taken along with line E-F of FIG. 7 according to aspects of the present disclosure; and

FIG. 9 is a cross-sectional view illustrating an example structure of the display panel according to aspects of the present disclosure.

### DETAILED DESCRIPTION

Reference will now be made in detail to example aspects of the present disclosure, examples of which may be illustrated in the accompanying drawings. In the following description, the structures, aspects, implementations, methods and operations described herein are not limited to the specific example or examples set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Advantages and features of the present disclosure, and implementation methods thereof will be clarified through following example aspects described with reference to the accompanying drawings. The present disclosure may, however, be embodied in different forms and should not be construed as limited to the example aspects set forth herein. Rather, these example aspects are provided so that this disclosure may be sufficiently thorough and complete to assist those skilled in the art to fully understand the scope of the present disclosure. Further, the protected scope of the present disclosure is defined by claims and their equivalents. In the following description, where the detailed description of the relevant known function or configuration may unnecessarily obscure aspects of the present disclosure, a detailed description of such known function or configuration may be omitted. The shapes, sizes, ratios, angles, numbers, and the like, which are illustrated in the drawings to describe various example aspects of the present disclosure, are merely given by way of example. Therefore, the present disclosure is not limited to the illustrations in the drawings. Where the terms “comprise,” “have,” “include,” “contain,” “constitute,” “make up of,” “formed of,” and the like are used, one or more other elements may be added unless the term, such as “only,” is used. An element described in the singular form is intended to include a plurality of elements, and vice versa, unless the context clearly indicates otherwise.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to”, “contacts or overlaps” etc. a second element, it should be interpreted that, not only may the first element “be directly connected or coupled to” or “directly contact or overlap” the second element, but a third element may also be “interposed” between the first and second elements, or the first and second elements may “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together. Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it should be considered that numerical values for an elements or features, or corresponding information (e. g., level, range, etc.) include a tolerance or error range that may be caused by various factors (e. g., process factors, internal or external impact, noise, etc.) even when a relevant description is not specified. Further, the term “may” fully encompasses all the meanings of the term “may”.

Hereinafter, with reference to the accompanying drawings, various example aspects of the present disclosure will be described in detail.

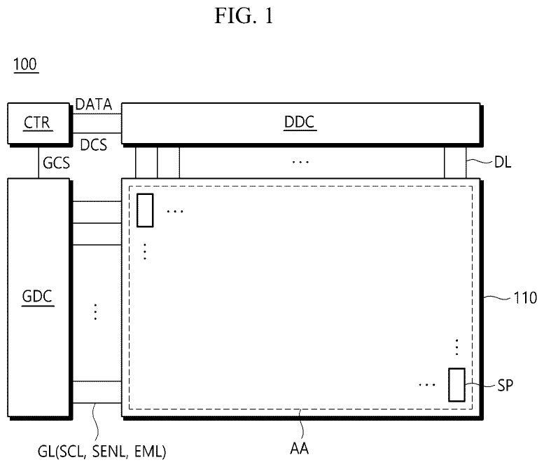

FIG. 1 illustrates an example system configuration of a display device according to aspects of the present disclosure.

In one or more aspects, the display device 100 may include a display panel 110 for displaying an image or producing light, and at least one driving circuit for driving the display panel 110.

In one or more aspects, the display device 100 may have a bottom emission structure in which light emitted from light emitting elements is directed toward a substrate over which the light emitting elements are disposed, but aspects of the present disclosure are not limited thereto.

For example, the display device 100 may have a top emission structure in which light emitted from light emitting elements is directed toward a surface or layer over the light emitting elements that is opposite to the substrate over which the light emitting elements are disposed, or a dual emission structure in which light emitted from light emitting elements is directed toward both the substrate and the surface or layer opposite to the substrate.

A plurality of data lines DL and a plurality of gate lines GL may be disposed in the display panel 110.

In one or more aspects, a plurality of subpixels SP defined by the plurality of data lines DL and the plurality of gate lines GL may be disposed in a matrix pattern in the display panel 110.

The plurality of data lines DL and the plurality of gate lines GL may be configured to intersect each other in the display panel 110.

For example, the plurality of gate lines GL may be disposed in one or more rows or columns, and the plurality of data lines DL may be disposed in one or more columns or rows.

Hereinafter, for convenience of description, discussions are provided based on examples where the plurality of gate lines GL are disposed in one or more rows and the plurality of data lines DL are disposed in one or more columns.

In addition to the plurality of data lines DL and the plurality of gate lines GL, other types of signal lines may be disposed in the display panel 110 according to a structure in which circuit elements are disposed in a subpixel, and the like.

At least one driving power line, at least one reference power line, at least one common power line, and the like may be additionally disposed in the display panel 110.

Types of signal lines disposed in the display panel 110 may be changed depending on a structure in which circuit elements are disposed in a subpixel, and the like.

Herein, one or more, of signal lines may configured to include a respective electrode to which a signal is applied. For example, at least a portion of a signal line may serve as an electrode to which a signal is applied.

The panel display 110 may include an active area A/A which allows images to be displayed, and a non-active area N/A which is an outer area or outer edge, and in which images are not displayed.

The non-active area N/A may be referred to as a bezel area or a bezel.

A plurality of subpixels SP for displaying images may be disposed in the active area A/A.

A pad area to which a data driver DDR and the like are electrically connected may be disposed in the non-active area N/A.

In one or more aspects, a plurality of data link lines for interconnecting the pad area and a plurality of data lines DL may be disposed in the non-active area N/A.

Here, the plurality of data link lines may be parts of the plurality of data lines DL extending to the non-active area N/A (e.g., from the active area A/A), or may be separate patterns electrically connected to the plurality of data lines DL.

In one or more aspects, gate driving related lines may be disposed in the non-active area N/A to deliver voltages (signals) needed for gate driving to a gate driver GDR through the pad portion to which the data driver DDR is electrically connected.

For example, the gate driving related lines may include clock lines for delivering clock signals, gate voltage lines for delivering gate voltages (VGH, VGL), gate driving control signal lines for delivering various types of control signals needed for generating scan signals, and the like.

The gate driving related lines may be disposed in the non-active area N/A, while the gate lines GL are at least partially disposed in the active area A/A.

The at least one driving circuit may include a data driver DDR for driving a plurality of data lines DL, a gate driver GDR for driving a plurality of gate lines GL, and a controller CTR for controlling the data driver DDR and the gate driver GDR.

The data driver DDR may drive the plurality of data lines DL by outputting data voltages to the plurality of data lines DL.

The gate driver GDR may drive the plurality of gate lines GL by outputting scan signals to the plurality of gate lines GL.

The controller CTR may control driving operations of the data driver DDR and the gate driver GDR by supplying various types of control signals (DCS, GCS) needed for the driving operations of the data driver DDR and the gate driver GDR.

Further, the controller CTR may supply image data DATA to the data driver DDR.

The controller CTR may start to scan pixels according to the timing of each frame.

The controller CTR may convert image data received from an internal or external device or system (e. g., a host system) to image data DATA readable by the data driver DDR, and then, output the image data DATA obtained by the converting to the data driver DDR. The controller CTR may control data driving so that data voltages corresponding to the image data DATA may be written into corresponding pixels at preset scan times.

To control the data driver DDR and the gate driver GDR, the controller CTR may receive, from the internal or external device or system (e. g., the host system), timing signals, such as, a vertical synchronization signal Vsync, a horizontal synchronization signal Hsync, an input data enable (DE) signal, a clock signal, and the like, and generate various types of control signals using the received signals.

Thereafter, the controller CTR may supply the generated signals to the data driver DDR and the gate driver GDR.

In one or more aspects, to control the gate driver GDR, the controller CTR may output several types of gate control signals GCS including a gate start pulse GSP, a gate shift clock GSC, a gate output enable signal GOE, and the like.

In one or more aspects, to control the data driver DDR, the controller CTR may output several types of data control signals DCS including a source start pulse SSP, a source sampling clock SSC, a source output enable signal SOE, and the like.

The controller CTR may be a timing controller used in the display of prior art.

In one or more aspects, the controller CTR may be a control apparatus/device capable of additionally performing any other control function in addition to the typical function of the timing controller.

For example, the controller CTR may be implemented in a separate component from the data driver DDR.

In one or more aspects, the controller CTR and the data driver DDR may be integrally formed in a single integrated circuit.

The data driver DDR may drive a plurality of data lines DL by receiving image data DATA from the controller CTR and then supplying data voltages (or data signals) corresponding to the image data DATA to the plurality of data lines DL.

The data driver DDR may also be referred to as a source driver.

The data driver DDR may transmit various signals to, or receive various signals from, the controller CTR through various interfaces.

The gate driver GDR may sequentially drive a plurality of gate lines GL by sequentially supplying scan signals to the plurality of gate lines GL.

The gate driver GDR may also be referred to as a scan driver.

According to the control of the controller CTR, the gate driver GDR may sequentially supply scan signals representing an on-voltage or an off-voltage to the plurality of gate lines GL.

When specific gate lines are selected and driven by the gate driver GDR, the data driver DDR may convert image data DATA received from the controller CTR into analog data voltages and supply the obtained data voltages to a plurality of data lines DL.

In one or more aspects, the data driver DDR may be located in, and/or electrically connected to, but not limited to, one side or edge (e.g., an upper portion or a lower portion) of the display panel PLN.

In one or more aspects, the data driver DDR may be located in, and/or electrically connected to, but not limited to, two sides or edges (e.g., an upper portion and a lower portion) of the display panel PLN according to driving schemes, panel design schemes, or other design requirements.

In one or more aspects, the gate driver GDR may be located in, and/or electrically connected to, but not limited to, one side or edge (e.g., a left portion or a right portion) of the display panel 110.

In one or more aspects, the data driver DDR may be located in, and/or electrically connected to, but not limited to, at least two of four sides or edges (e.g., an upper portion, a lower portion, a left portion, and a right portion) of the display panel PLN according to driving schemes, panel design schemes, or other design requirements.

In one or more aspects, the gate driver GDR may be located in, and/or electrically connected to, but not limited to, two sides or edges (e.g., a left portion and a right portion) of the display panel PLN according to driving schemes, panel design schemes, or other design requirements.

In one or more aspects, the gate driver GDR may be located in, and/or electrically connected to, but not limited to, at least two of four sides or edges (e.g., an upper portion, a lower portion, a left portion, and a right portion) of the display panel PLN according to driving schemes, panel design schemes, or other design requirements.

The data driver DDR may be implemented by including one or more source driver integrated circuits SDIC.

Each source driver integrated circuit SDIC may include a shift register, a latch circuit, a digital-to-analog converter DAC, an output buffer, and the like.

In one or more aspects, the data driver DDR may further include one or more analog-to-digital converters ADC.

Each source driver integrated circuit SDIC may be connected to a conductive pad such as a bonding pad of the display panel 110 by a tape-automated-bonding (TAB) technique or a chip-on-glass (COG) technique.

In one or more aspects, each source driver integrated circuit SDIC may be directly disposed in the display panel 110.

In one or more aspects, each source driver integrated circuit SDIC may be integrated into the display panel 110 in the form of an integrated chip.

In one or more aspects, each source driver integrated circuit SDIC may be connected to the display panel 110 by a chip-on-film (COF) technique.

In this implementation, each source driver integrated circuit SDIC may be mounted on a circuit film.

Each source driver integrated circuit SDIC mounted on the circuit film may be electrically connected to at least one data line DL in the display panel 110 through the circuit film.

The gate driver GDR may include a plurality of gate driving circuits GDC.

The plurality of gate driving circuits GDC may correspond to a plurality of gate lines GL, respectively.

Each gate driving circuit GDC may include a shift register, a level shifter, and the like.

Each gate driving circuit GDC may be connected to a conductive pad such as a bonding pad of the display panel 110 by the tape-automated-bonding (TAB) technique or the chip-on-glass (COG) technique.

In one or more aspects, each gate driving circuit GDC may be implemented by the chip-on-film (COF) technique.

In this implementation, each gate driving circuit GDC may be mounted on a circuit film.

Each gate driving circuit GDC mounted on the circuit film may be electrically connected to at least one gate line GL in the display panel 110 through the circuit film.

In one or more aspects, each gate driving circuit GDC may be embedded into the display panel 110 by a gate-in-panel (GIP) technique.

Accordingly, each gate driving circuit GDC may be directly formed in the display panel 110.

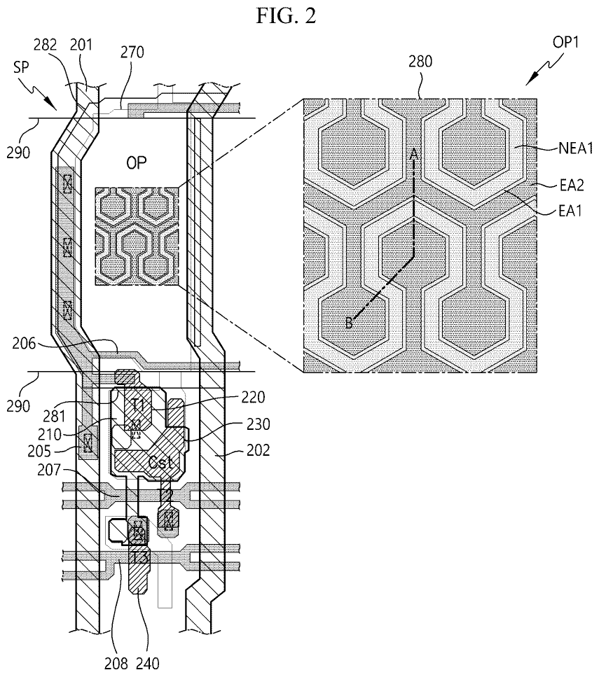

FIG. 2 is a plan view of an example area where subpixels are disposed in the active area A/A of the display panel 110 according to aspects of the present disclosure.

Referring to FIG. 2, in one or more aspects, at least one subpixel SP of a plurality of subpixels SP included in the display device 100 may include an area overlapping with a bank layer 290 and an area overlapping with an open area OP of the bank layer 290.

The area overlapping with the bank layer 290 may include a non-light emitting area. For example, a plurality of signal lines (201, 202, 203, 204, 205, 206, 207, 208), a light shield layer 210, and a plurality of active layers (220, 230, 240) may be disposed in the non-light emitting area.

The plurality of signal lines may include first to eighth signal lines (201, 202, 203, 204, 205, 206, 207, and 208), and the plurality of active layers may include first to third active layers (220, 230, and 240).

Referring to FIG. 2, a plurality of transistors (T1, T2, T3) and a storage capacitor Cst for driving a light emitting element disposed in a subpixel SP may be disposed in the area overlapping with the bank layer 290.

The light emitting element including a first electrode, an organic layer, and a second electrode may be disposed in the open area OP of the bank layer 290.

In one or more aspects, one or more color filters (281, 282) may be disposed in the area overlapping with the open area OP, but aspects of the present disclosure are not limited thereto.

For example, color filters may be disposed only in some of subpixels SP included in the display device 100, or color filters may not be disposed in all of the subpixels SP included in the display device 100.

In an example where one or more color filters (281, 282) are disposed in a subpixel SP, as shown in FIG. 2, the one or more color filters (281, 282) may overlap with a plurality of light emitting areas (EA1, EA2).

Referring to FIG. 2, in one or more aspects, the display device 100 may be provided with a plurality of light emitting areas (EA1, EA2) formed in an area overlapping with each open area OP of the bank layer 290.

For example, a plurality of first light emitting areas EA1, a plurality of second light emitting areas EA2, and a plurality of first non-light emitting areas NEA1 may be formed in one open area OP formed in one subpixel SP.

Referring to FIG. 2, the plurality of first non-light emitting areas NEA1 may be configured to be spaced apart from each other in the area overlapping with the open area OP of the bank layer 290.

In one or more aspects, the plurality of second light emitting areas EA2 may be surrounded by the first light emitting areas EA1.

In one or more aspects, the plurality of first non-light emitting areas NEA1 may be surrounded by the first light emitting areas EA1.

Referring to FIG. 2, the plurality of first non-light emitting areas NEA1 disposed in at least one subpixel SP may include first and second grooves configured to alternate with each other in at least a portion of the plurality of first non-light emitting area NEA1. However, aspects of the present disclosure are not limited thereto, and for example, the plurality of first non-light emitting areas NEA1 may be disposed in various shapes as described below.

Referring to FIG. 2, the plurality of first non-light emitting areas NEA1, the plurality of first light emitting areas EA1, and the plurality of second light emitting areas EA2 overlapping with the open area OP in at least one subpixel SP may overlap with one or more color filters (281, 282).

Respective luminance of the plurality of first light emitting areas EA1 and the plurality of second light emitting areas EA2 included in one subpixel SP may be the same as each other.

However, light emitting characteristics in the display device 100 according to aspects of the present disclosure are not limited thereto. For example, the luminance of the plurality of first light emitting areas EA1 included in one subpixel SP may be less than that of one second light emitting area EA2 included in the subpixel SP.

Each second light emitting area EA2 may be configured to surround at least a portion of corresponding one of the plurality of first light emitting areas EA1.

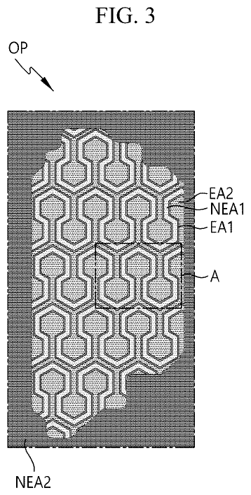

FIG. 3 is a plan view of example light emitting areas in the display device 100 according to aspects of the present disclosure.

Referring to FIG. 3, in one or more aspects, the display device 100 may include a plurality of light emitting areas (EA1, EA2) and a plurality of first non-light emitting areas NEA1 in one subpixel.

For example, the plurality of light emitting areas (EA1, EA2) may be disposed in one open area OP of the bank layer, and as illustrated in FIG. 3, the plurality of first non-light emitting areas NEA1 may be disposed in the open area OP of the bank layer.

Referring to FIG. 3, the plurality of first non-light emitting areas NEA1 disposed in the open area OP of the bank layer may include first and second grooves configured to alternate with each other in at least a portion of first non-light emitting areas NEA1. However, aspects of the present disclosure are not limited thereto, and for example, the plurality of first non-light emitting areas NEA1 may be disposed in various shapes as described below.

Referring to FIG. 3, the plurality of first non-light emitting areas NEA1 disposed in the open area OP of the bank layer may be configured to be spaced apart from each other.

The plurality of first light emitting areas EA1 disposed in one subpixel may be areas where light emitted from an emission layer is reflected toward the substrate by a reflective electrode disposed in the first non-light emitting areas NEA1, and then, exit the substrate.

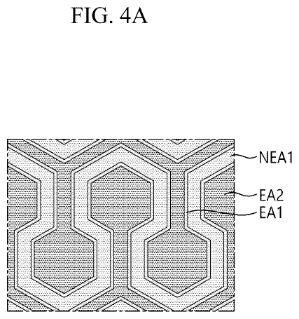

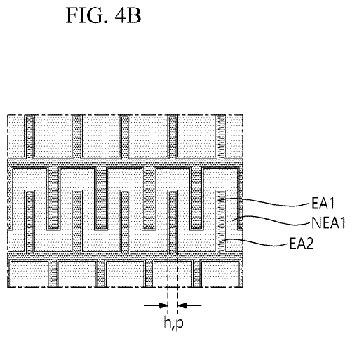

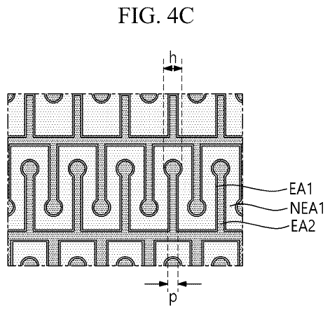

FIGS. 4A to 4C are enlarged plan views of area A in FIG. 3 according to aspects of the present disclosure.

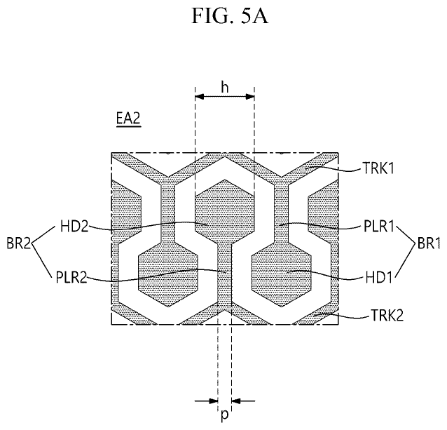

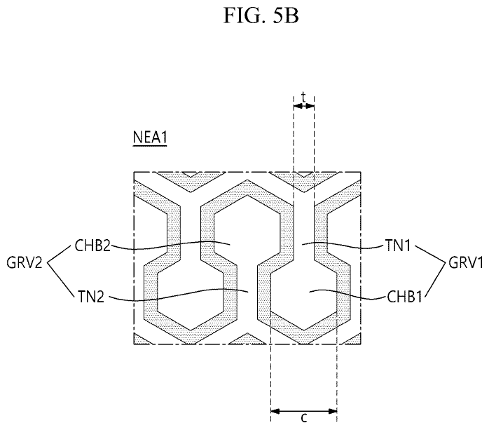

FIGS. 5A and 5B are example plan views illustrating a light emitting area and a non-light emitting area of FIG. 4A according to aspects of the present disclosure.

Referring to FIGS. 4A and 5A, a second light emitting area EA2 may include at least one trunk portion (TRK1, TRK2) and at least one branch portion (BR1, BR2) connected to the at least one trunk portion (TRK1, TRK2).

Each trunk portion (TRK1, TRK2) may have a zigzag shape as shown in FIG. 4A, but aspects of the present disclosure are not limited thereto. For example, each trunk portion (TRK1, TRK2) may have a straight shape as shown in FIGS. 4B and 4C.

FIGS. 4A to 4C illustrate that each trunk portion (TRK1, TRK2) has a zigzag shape or a straight shape, but these are only some examples of applicable examples. For example, each trunk portion (TRK1, TRK2) may have various shapes such as a curve and the like.

Referring to FIG. 5A, the at least one trunk portion (TRK1, TRK2) included in the second light emitting area EA2 may include a first trunk portion TRK1 and a second trunk portion TRK2 disposed adjacent to the first trunk portion TRK1.

In one or more aspects, the at least one branch portions (BR1, BR2) included in the second light emitting area EA2 may include at least one first branch portion BR1 connected to the first trunk portion TRK1 and at least one second branch portion BR2 connected to the second trunk portion TRK2.

Referring to FIG. 5A, the first branch portion BR1 and the second branch portion BR2 may be arranged alternately.

Referring to FIG. 5A, each branch portion (BR1 or BR2) may include a head portion (HD1 or HD2) and a filler portion (PLR1 or PLR2) connecting the head portion (HD1 or HD2) and the trunk portion (TRK1 or TRK2).

For example, each first branch portion BR1 may include a first head portion HD1 and a first filler portion PLR1 connecting the first head portion HD1 and the first trunk portion TRK1.

Each second branch portion BR2 may include a second head portion HD2 and a second filler portion PLR2 connecting the second head portion HD2 and the second trunk portion TRK2.

In the example where each branch portion (BR1 or BR2) includes the head portion (HD1 or HD2) and the filler portion (PLR1 or PLR2) connecting the head portion (HD1 or HD2) and the trunk portion (TRK1 or TRK2), a width h of the head portion (HD1 or HD2) may be greater than a width p of the filler portion (PLR1 or PLR2), but aspects of the present disclosure are not limited thereto.

A width of the first head portion HD1 may be greater than a width of the first filler portion PLR1, but aspects of the present disclosure are not limited thereto.

A width of the second head portion HD2 may be greater than a width of the second filler portion PLR2, but aspects of the present disclosure are not limited thereto.

Referring to FIG. 4B, a width of each head portion (HD1 and HD2) and a width of each filler portion (PLR1 and PLR2) may be the same.

Referring to FIG. 4A and FIG. 5A, each head portion (HD1 and HD2) may have a regular hexagonal shape, but aspects of the present disclosure are not limited thereto.

For example, referring to FIG. 4B, each head portion (HD1 and HD2) may have a rectangular shape.

For example, referring to FIG. 4C, each head portion (HD1 and HD2) may have a circular shape.

Referring to FIG. 5B, a first non-light emitting area NEA1 may include at least one first groove GRV1 and at least one second groove GRV2, which are alternately disposed with each other in at least a portion of the first non-light emitting area NEA1.

In this implementation, respective areas of each first groove GRV1 and each second groove GRV2 may be the same, but aspects of the present disclosure are not limited thereto.

Referring to FIG. 5B, each first groove GRV1 may include a first chamber portion CHB1 and a first passage portion TN1.

The first passage portion TN1 may connect the first chamber portion CHB1 to an area other than an area where the first groove GRV1 and the second groove GRV2 are disposed.

Referring to FIG. 5B, each second groove GRV2 may include a second chamber portion CHB2 and a second passage portion TN2.

The second passage portion TN2 may connect the second chamber portion CHB2 and an area other than an area where the first groove GRV1 and the second groove GRV2 are disposed.

Referring to FIG. 5B, a width c of each chamber portion (CHB1 and CHB2) may be greater than a width t of each passage portion (TN1 and TN2), but aspects of the present disclosure are not limited thereto.

Each chamber part (CHB1 and CHB2) may have a regular hexagonal shape, but aspects of the present disclosure are not limited thereto.

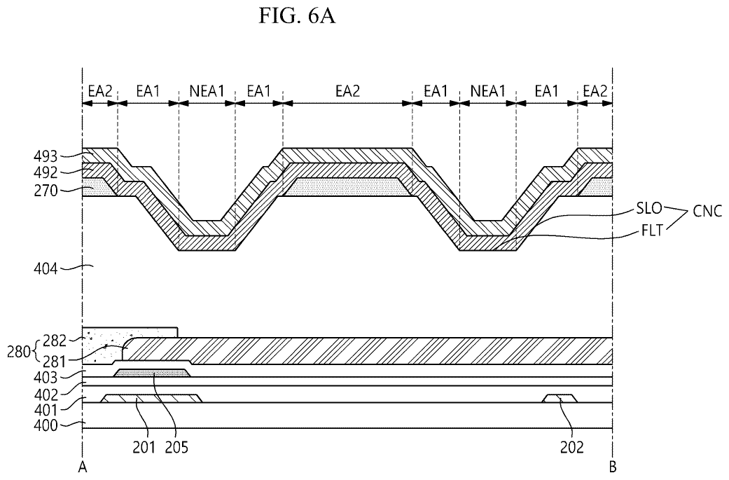

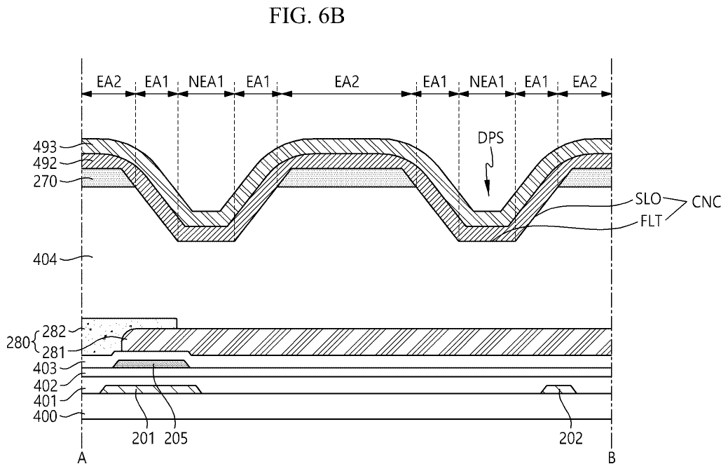

FIGS. 6A and 6B are example cross-sectional views taken along line A-B of FIG. 2 according to aspects of the present disclosure.

Referring to FIGS. 6A and 6B, a first signal line 201 and a second signal line 202 may be disposed on a substrate 400.

A first insulating layer 401 may be disposed on the first and second signal lines (201 and 202).

The first insulating layer 401 may be a buffer layer and may be a single layer or include multiple layers.

A second insulating layer 402 may be disposed on the first insulating layer 401.

In this implementation, the second insulating layer 402 may be a gate insulating layer.

The first and second insulating layers (401 and 402) may include an inorganic insulating material such as silicon oxide (SiOx), silicon nitride (SiNx), silicon oxynitride (SiON) and the like, but aspects of the present disclosure are not limited thereto.

A fifth signal line 205 may be disposed on the second insulating layer 402.

Each of the first signal line 201, the second signal line 202, and the fifth signal line 205 may include a conductive material.

For example, each signal line (201, 202, and 205) may include any one of either a metal such as aluminum (Al), gold (Au), silver (Ag), copper (Cu), tungsten (W), molybdenum (Mo), chromium (Cr), tantalum (Ta), titanium (Ti), and the like, or an alloy of one or more alloys thereof, but aspects of the present disclosure are not limited thereto.

In one or more aspects, third and fourth signal lines (203 and 204) illustrated in FIG. 2 may include the same material as the first and second signal lines (201 and 202), but aspects of the present disclosure are not limited thereto.

A third insulating layer 403 may be disposed on the fifth signal line 205.

At least one color filter 280 may be disposed on the third insulating layer 403.

The at least one color filter 280 may include a first color filter 281 and a second color filter 282. For example, the first color filter 281 and the second color filter 282 may be color filters of different colors.

For example, the first color filter 281 may be a red color filter, and the second color filter 282 may be a green color filter.

FIGS. 6A and 6B illustrate that the at least one color filter 280 includes the first color filter 281 and the second color filter 282, but aspects of the present disclosure are not limited thereto. For example, the color filter 280 disposed on the third insulating layer 403 may further include one or more color filters in addition to the first and second color filters (281 and 282).

For example, a blue color filter with a blue color that is different from the colors of the first and second color filters (281 and 282) may be further disposed on the third insulating layer 403, or one or more color filters with the same color as at least one of the colors of the first and second color filters (281 and 282) may be further disposed on the third insulating layer 403.

Referring to FIGS. 6A and 6B, one end of the first color filter 281 may overlap with one edge of the second color filter, or one edge of the first color filter 281 may overlap with one end of the second color filter

An area where respective portions of the first and second color filters (281 and 282) overlap with each other may serve as a black matrix.

A fourth insulating layer 404 may be disposed on the at least one color filter 280.

The fourth insulating layer 404 may include an organic insulating material, but aspects of the present disclosure are not limited thereto.

Referring to FIGS. 6A and 6B, a plurality of anode electrodes 270 (or portions of an anode electrode 270) may be disposed on the fourth insulating layer 404.

The anode electrode 270 may be referred to as a first electrode.

The anode electrode 270 may include a transparent conductive material.

For example, the anode electrode 270 may include at least one of indium tin oxide (ITO), indium zinc oxide (IZO), or indium gallium zinc oxide (IGZO), but aspects of the present disclosure are not limited thereto. For example, the anode electrode 270 may be configured with any material having high light transmittance and high conductivity.

Referring to FIGS. 6A and 6B, in one subpixel, the plurality of anode electrodes 270 (or the portions of the anode electrode 270) may be configured to be spaced apart from each other on the fourth insulating layer 404.

Referring to FIGS. 6A and 6B, in an area between at least two anode electrodes 270 (or at least two portions of the anode electrode 270), at least one depressed portion CNC may be formed in the fourth insulating layer 404.

For example, referring to FIGS. 6A and 6B, the anode electrodes 270 (or the portions of an anode electrode 270) may be configured to be spaced apart from each other on the fourth insulating layer 404.

In one or more aspects, the fourth insulating layer 404 may include at least one depressed portion CNC.

Each depressed portion CNC may include a flat portion FLT and an inclined portion SLO surrounding the flat portion FLT.

The anode electrodes 270 (or the portions of an anode electrode 270) may be disposed in an area other than the at least one depressed portion CNC.

In one or more aspects, the anode electrode 270 may not overlap with a portion of the upper surface of the fourth insulating layer 404 in an area other than the depressed portion CNC of the fourth insulating layer 404.

Referring to FIGS. 6A and 6B, a bank layer (not shown) may include an open area OP, and be disposed on the fourth insulating layer 404 and disposed on at least a portion of the upper surface of the anode electrode 270.

The bank layer (not shown) may include a transparent organic material or a black organic material.

Referring to FIGS. 6A and 6B, an emission layer 492 may be disposed over the substrate 400 over which the anode electrode 270 and the bank layer (not shown) are disposed, and a cathode electrode 493 may be disposed on the emission layer 492.

FIGS. 6A and 6B illustrate that each of the emission layer 492 and the cathode electrode 493 is a single layer, but aspects of the present disclosure are not limited thereto. For example, at least one of the emission layer 492 and the cathode electrode 493 may include multiple layers.

Referring to FIGS. 6A and 6B, the emission layer 492 and the cathode electrode 493 may be disposed on the bank layer (not shown) and the open area.

The cathode electrode 493 may include a conductive material reflecting light.

For example, the cathode electrode 493 may include any one of either a metal such as aluminum (Al), magnesium (Mg), gold (Au), silver (Ag), copper (Cu), tungsten (W), molybdenum (Mo), chromium (Cr), tantalum (Ta), titanium (Ti), and the like, or one of one or more alloys thereof, but aspects of the present disclosure are not limited thereto.

Referring to FIGS. 6A and 6B, the emission layer 492 and the cathode electrode 493 may be disposed on the depressed portion CNC of the fourth insulating layer 404 overlapping with the open area.

Referring to FIGS. 6A and 6B, the emission layer 492 and the cathode electrode 493 may be formed along the morphology of the anode electrode 270 and the fourth insulating layer 404 in the open area.

Referring to FIG. 6A, each of the emission layer 492 and the cathode electrode 493 may overlap with the anode electrode 270 and the depressed portion CNC in the open area, and may have a step portion in the open area.

In one or more aspects, referring to FIG. 6A, each of the emission layer 492 and the cathode electrode 493 may overlap with the anode electrode 270 and the depressed portion CNC in the open area, and may have a lowered portion DPS with a round shape.

Referring to FIG. 6A, both ends of the depressed portion CNC and respective ends of portions of the anode electrode 270 adjacent to the ends of the depressed portion CNC may contact each other to form the lowered portion DPS with the round shape, but aspects of the present disclosure are not limited thereto.

Referring to FIGS. 6A and 6B, one subpixel may include a first light emitting area EA1, a second light emitting area EA2, a first non-light emitting area NEA1, and a second non-light emitting area (not shown).

The first light emitting area EA1, the second light emitting area EA2, and the first non-light emitting area NEA1 may be formed at a location where an open area of the bank layer (not shown) is present.

The second non-light emitting area (not shown) may be an area where the bank layer (not shown) is disposed.

Referring R to FIGS. 6A and 6B, the first non-light emitting area NEA1 may overlap with the depressed portion CNC of the fourth insulating layer 404.

For example, the first non-light emitting area NEA1 may be an area where a distance in the vertical direction between the substrate 400 and the bottom surface of the cathode electrode 493 is the shortest in the open area of the bank layer (not shown) in the cross-sectional view.

The first non-light emitting area NEA1 may be an area corresponding to at least a portion of the flat portion FLT of the depressed portion CNC.

The first light emitting area EA1 may be an area corresponding to the inclined portion SLO of the depressed portion CNC.

The first light emitting area EA1 may surround the first non-light emitting area NEA1.

The second light emitting area EA2 may be an area corresponding to an area where the anode electrode 270 is disposed.

The second light emitting area EA2 may surround the first light emitting area EA1.

In the second light emitting area EA2, first part of light emitted from the emission layer 492 may emit from the emission layer 492, pass through the anode electrode 270, and then, reach and exit the substrate 400.

In one or more aspects, second part of the light emitted from the emission layer 492 may emit to the cathode electrode 493 from the emission layer 492, then reflected by the cathode electrode 493 including a reflective conductive material toward the anode electrode 270, pass through the anode electrode 270, and thereafter, reach and exit the substrate 400.

In one or more aspects, third part of the light emitted from the emission layer 492 disposed between the anode electrode 270 and the cathode electrode 493 may emit in a direction crossing a direction in which the buffer layer 401 is stacked on the substrate 400, then reflected from the cathode electrode 493 located in the first light emitting area EA1 and reflected toward the substrate 400, and thereafter, reach and exit the substrate 400.

For example, referring to FIG. 6A, the third part of the light emitted from the emission layer 492 disposed between the anode electrode 270 and the cathode electrode 493 may reach a step portion of the cathode electrode 493, and then reflected from the step portion and reflected toward the substrate 400 to enable the reflected light to exit the substrate 400.

In this situation, since the third part of the light emitted from the emission layer 492 may be caused to move to the outside through the step portion without loss, resulting emission efficiency may be improved.

In one or more aspects, as part of the light emitted by the anode electrode 270, the emission layer 492, and the cathode electrode 493 disposed in the second light emitting area EA2 is reflected by the reflective conductive material included in the cathode electrode 493, the first light emitting area EA1 may be a light emitting area formed by the reflected light.

In one or more aspects, since the depressed portion CNC may be formed simultaneously in the process of forming a contact hole for electrically connecting the anode electrode 270 disposed on the fourth insulating layer 404 to a transistor, a separate process for forming the depressed portion CNC may not be needed.

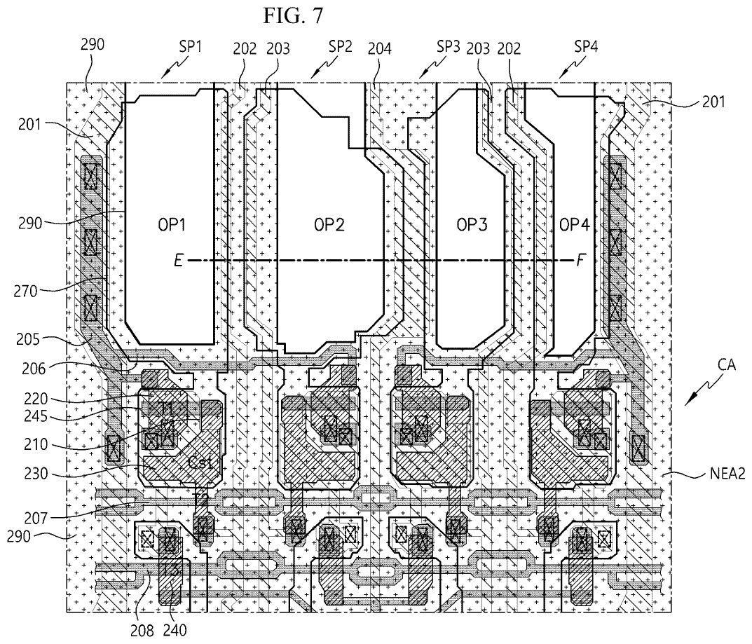

Hereinafter, an example structure of the display device 100 according to aspects of the present disclosure are discussed with reference to FIG. 7.

FIG. 7 is an example plan view illustrating the structure of four subpixels in the display device 100 according to aspects of the present disclosure.

Referring to FIG. 7, in one or more aspects, the display device 100 may include a first subpixel SP1, a second subpixel SP2, a third subpixel SP3, and a fourth subpixel SP4.

The first to fourth subpixels (SP1, SP2, SP3, and SP4) may include light emitting areas emitting light of different colors.

For example, the first subpixel SP1 may include a light emitting area emitting red light, the second subpixel SP2 may include a light emitting area emitting white light, the third subpixel SP3 may include a light emitting area emitting blue light, and the fourth subpixel SP4 may include a light emitting area emitting green light.

Referring to FIG. 7, each of the first to fourth subpixels (SP1, SP2, SP3, and SP4) may include a plurality of transistors (T1, T2, and T3) and a storage capacitor Cst disposed in a circuit area CA.

For example, a corresponding circuit area CA of each of the first to fourth subpixels (SP1, SP2, SP3, and SP4) may include a first transistor T1, a second transistor T2, a third transistor T3, and a storage capacitor Cst.

Referring to FIG. 7, the circuit area CA of each of the first to fourth subpixels (SP1, SP2, SP3, and SP4) may overlap with a bank layer 290.

For example, the bank layer 290 may overlap with the first transistor T1, the second transistor T2, the third transistor T3, and the storage capacitor Cst.

For example, the bank layer 290 may overlap with a gate electrode 245 and a first active layer 220 included in the first transistor T1, overlap with a second active layer 230 included in the second transistor T2, overlap with a third active layer 240 included in the third transistor T3, and overlap with a light shield layer 210, which is one of electrodes of the storage capacitor Cst.

Referring to FIG. 7, the bank layer 290 may overlap with a plurality of signal lines (201, 202, 203, 204, 205, 206, 207, 208) needed to drive light emitting elements.

In one or more aspects, one or more of the plurality of signal lines (201, 202, 203, 204, 205, 206, 207, 208) may serve as any one of a source electrode, a drain electrode, and a gate electrode of each transistor (T1, T2, T3).

Referring to FIG. 7, an area where the bank layer 290 is disposed may be substantially the same as a second non-light emitting area NEA2 of the active area A/A.

Herein, substantially the same may mean a degree of being considered as being equivalent to each other taking into account minute differences due to errors in the process of manufacturing the display panel 110 or display device 100.

Referring to FIG. 7, the bank layer 290 may include a first open area OP1, a second open area OP2, a third open area OP3, and a fourth open area OP4.

The first open area OP1 may be included in the first subpixel SP1, the second open area OP2 may be included in the second subpixel SP2, the third open area OP3 may be included in the third subpixel SP3, and the fourth open area OP4 may be included in the fourth subpixel SP4.

Referring to FIG. 7, each of the first to fourth open areas (OP1, OP2, OP3, and OP4) may include a plurality of light emitting areas (EA1, EA2, EA3) and a plurality of first non-light emitting areas NEA1.

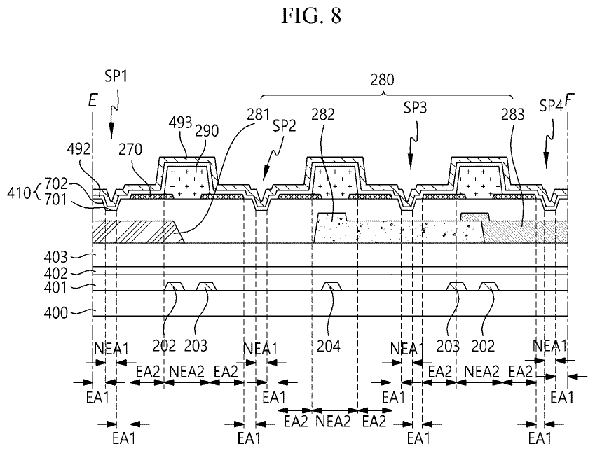

FIG. 8 is an example cross-sectional view taken along with line E-F of FIG. 7 according to aspects of the present disclosure.

Referring to FIG. 8, each of the first subpixel SP1, the second subpixel SP2, the third subpixel SP3, and the fourth subpixel SP4 may include a plurality of first light emitting areas EA1 and a plurality of second light emitting areas EA2.

For example, referring to FIG. 8, each of the first to fourth subpixels (SP1, SP2, SP3, and SP4) may be provided with a depressed portion of a fourth insulating layer 404 located in an area corresponding to an open area OP of the bank layer 290.

An area corresponding to a flat portion of the depressed portion of the fourth insulating layer 404 in each of the first to fourth subpixels (SP1, SP2, SP3, and SP4) may be a first non-light emitting area NEA1.

Each of the first to fourth subpixels (SP1, SP2, SP3, and SP4) may include at least one first non-light emitting area NEA1, which is disposed in the open area OP of the bank layer 290.

Referring to FIG. 8, the first non-light emitting areas NEA1 of each of the first subpixel SP1, the third subpixel SP3, and the fourth subpixel SP4 may overlap with a color filter 280.

In each of the first to fourth subpixels (SP1, SP2, SP3, and SP4), an area corresponding to an inclined portion of the depressed portion of the fourth insulating layer 404 may be the first light emitting area EA1.

In one or more aspects, in the open area of the bank layer 290 located in each of the first to fourth subpixels (SP1, SP2, SP3, and SP4), an area where the anode electrode 270 does not overlap with the fourth insulating layer 404 in the remaining area except for the depressed portion may also be included in the first light emitting area EA1.

Referring to FIG. 8, in the open area of the bank layer 290 located in each of the first to fourth subpixels (SP1, SP2, SP3, and SP4), an area where the fourth insulating layer 404 overlaps with the anode electrode 270 may be the second light emitting area EA2.

In the first to fourth subpixels (SP1, SP2, SP3, and SP4), an area overlapping with the bank layer 290 may be the second non-light emitting area NEA2.

Referring to FIG. 8, a plurality of signal lines (202, 203, and 204) may be configured to overlap with the bank layer 290.

Each of the plurality of signal lines (202, 203, and 204) may not overlap with the first and second light emitting areas (EA1 and EA2).

Accordingly, light emitted from the first and second light emitting areas (EA1 and EA2) of the first to fourth subpixels (SP1, SP2, SP3, and SP4) may be prevented from being lost by the plurality of signal lines (202, 203, 204).

Referring to FIG. 8, as first to fourth insulating layers (401, 402, 403, and 404) and the bank layer 290 are disposed between the plurality of signal lines (202, 203, 204) and the cathode electrode 493, a corresponding distance between each of the plurality of signal lines (202, 203, 204) and the cathode electrode 493 may be increased.

Accordingly, corresponding parasitic capacitance between each of the plurality of signal lines (202, 203, 204) and the cathode electrode 493 may be reduced.

Here, the distance between each of the plurality of signal lines (202, 203, 204) and the cathode electrode 493 may mean a shortest straight line length between the top surface of each of the plurality of signal lines (202, 203, 204) and the bottom surface of the cathode electrode 493.

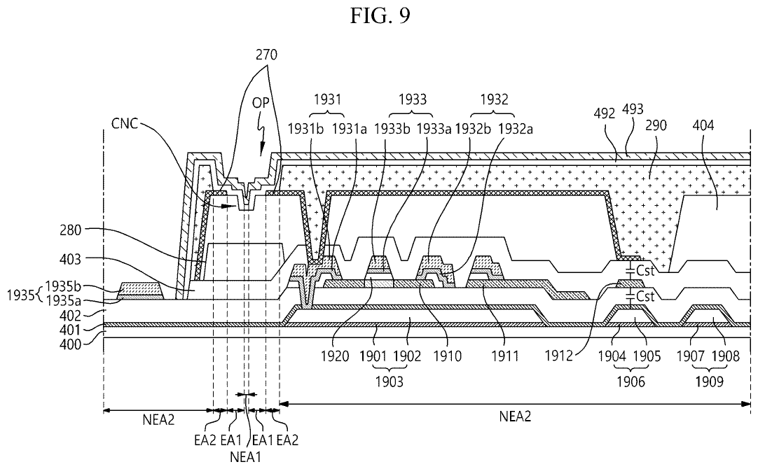

Hereinafter, an example structure of the display panel 110 according to aspects of the present disclosure is discussed with reference to FIG. 9.

FIG. 9 is an example cross-sectional view illustrating the structure of the display panel 110 according to aspects of the present disclosure.

Referring to FIG. 9, in one or more aspects, the display panel 100 may include at least one thin film transistor and at least one light emitting element disposed over the substrate 400.

In one or more aspects, a plurality of signal lines (1903 and 1909) and a light shield layer 1906 may be disposed on the substrate 400.

Each of the signal lines (1903 and 1909) of FIG. 9 may be any one of the plurality of signal lines (201, 202, 201 and 202) illustrated in FIG. 7.

Each of the signal lines (1903 and 1909) may include multiple layers.

For example, one signal line 1903 may include a first layer 1901 and a second layer 1902 disposed on the first layer 1901, and another signal line 1909 may include a fifth layer 1907 and a sixth layer 1908 disposed on the fifth layer 1907.

Likewise, the light shield layer 1906 may include a third layer 1904 and a fourth layer 1905 disposed on the third layer 1904.

The first layer 1901, the third layer 1904, and the fifth layer 1907 may include the same material, and the second layer 1902, the fourth layer 1905, and the sixth layer 1908 may include the same material.

A first insulating layer 401 and a second insulating layer 402 may be sequentially disposed on the plurality of signal lines (1903 and 1909) and the light shield layer 1906.

A thin film transistor and a plurality of electrodes may be disposed on the second insulating layer 402.

For example, referring to FIG. 9, a first active layer 1910, a second active layer 1911, and a third active layer 1912 may be disposed on the second insulating layer 402 in the active area A/A of the display panel 110.

At least one active layer among the first to third active layers (1910, 1911, and 1912) may include an oxide semiconductor material.

The oxide semiconductor material may be a semiconductor material obtained by controlling conductivity and adjusting a band gap through doping in an oxide material, and may be a transparent semiconductor material having a relatively wide band gap.

For example, the oxide semiconductor material may include indium gallium zinc oxide (IGZO), zinc oxide (ZnO), indium gallium oxide (IGO), indium zinc oxide (IZO), cadmium oxide (CdO), indium oxide (InO), zinc tin oxide (ZTO), zinc indium tin oxide (ZITO), indium gallium zinc tin oxide (IGZTO), and the like.

A gate insulating layer 1920 may be disposed on the first active layer 1910 and the second active layer 1911.

Each of the first to third active layers (1910, 1911, and 1912) may be in a conductive state in areas not overlapping with the gate insulating layer 1920.

For example, respective portions of the first to third active layers (1910, 1911, and 1912) not overlapping with the gate insulating layer 1920 may be conductive portions.

Referring to FIG. 9, the third active layer 1912 may become conductive and serve as an electrode, and the third active layer 1912 may form a storage capacitor Cst with a signal line 1906 disposed under the third active layer 1912.

Referring to FIG. 9, the gate insulating layer 1920 may be disposed on a portion of the upper surface of the first active layer 1910 and a portion of the upper surface of the second active layer 1911.

In the active area, a source electrode 1931, a drain electrode 1932, and a gate electrode 1933 may be disposed on the gate insulating layer 1920.

However, aspects of the present disclosure are not limited thereto, and the drain electrode 1931, the source electrode 1932, and the gate electrode 1933 may be disposed on the gate insulating layer 1920.

In one or more aspects, in the non-active area of the display panel 110, the source electrode 1931, the drain electrode 1932, and the gate electrode 1933 may be disposed in the same layer and may include the same material.

In one or more aspects, as illustrated in FIG. 9, a pad electrode 1935 may be disposed on the second insulating layer 402.

For example, the source electrode 1931, the drain electrode 1932, the gate electrode 1933, and the pad electrode 1935 may include multiple layers.

For example, each of the source electrode 1931, the drain electrode 1932, the gate electrode 1933, and the pad electrode 1935 may include two or more layers, but aspects of the present disclosure are not limited thereto. For example, at least one of the source electrode 841, the drain electrode 842, the gate electrode 843, and the pad electrode 845 may be a single layer.

A first layer 1931a of the source electrode 1931, a first layer 1932a of the drain electrode 1932, a first layer 1933a of the gate electrode 1933, and a first layer 1935a of the pad electrode 1935 may include the same material, and a second layer 1931b of the source electrode 1931, a second layer 1932b of the drain electrode 1932, a second layer 1933b of the gate electrode 1933, and a second layer 1935b of the pad electrode 1935 may include the same material. However, aspects of the present disclosure are not limited thereto. For example, the first layer 841a of the source electrode 841, the first layer 842a of the drain electrode 842, the first layer 843a of the gate electrode 843, and the first layer 845a of the pad electrode 845 may include different materials, and the second layer 841b of the source electrode 841, the second layer 842b of the drain electrode 842, the second layer 843b of the gate electrode 843, and the second layer 845b of the pad electrode 845 may include different materials.

A third insulating layer 403 may be disposed over the substrate 400 over which the source electrode 1931, the drain electrode 842, and the gate electrode 843 are disposed in the active area.

At least one color filter 280 may be disposed on the third insulating layer 403.

The at least one color filter 280 may overlap with a plurality of light emitting areas (EA1, EA2) in one subpixel.

A fourth insulating layer 404 may be disposed on the at least one color filter 280.

In one or more aspects, the fourth insulating layer 404 may include at least two holes and at least one depressed portion CNC in one subpixel.

For example, referring to FIG. 9, the depressed portion CNC of the fourth insulating layer 404 may overlap with a portion of the color filter 280.

However, aspects of the present disclosure are not limited thereto. For example, the depressed portion CNC of the fourth insulating layer 404 may be located even in a subpixel where a color filter 280 is not disposed.

Referring to FIG. 9, one hole among the at least two holes of the fourth insulating layer 404 may be formed on the source electrode 1931, and overlap with a hole in the third insulating layer 403 and expose a portion of the upper surface of the source electrode 1931.

Another hole among the at least two holes of the fourth insulating layer 404 may be located in an area overlapping with the third active layer 1912.

An anode electrode 270 may be disposed on the fourth insulating layer 404.

For example, anode electrodes 270 (or portions of the anode electrode 270) may be configured to be spaced apart from each other with at least one concave portion CNC of the fourth insulating layer 404 interposed therebetween in the cross-sectional view.

At least one of the anode electrodes (or at least one of the portions of the anode electrode 270) may be electrically connected to the source electrode 1931 of the thin film transistor.

Referring to FIG. 9, at least one of the anode electrodes (or at least one of the portions of the anode electrode 270) may be disposed in a portion of the inside of a hole overlapping with the third active layer 1912 among the holes formed in the fourth insulating layer 404.

Therefore, the at least one of the anode electrodes (or the at least one of the portions of the anode electrode 270) may form a storage capacitor Cst by overlapping with the third active layer 1912 in the inside of the hole of the fourth insulating layer 404.

In this way, each of the light shield layer 1906, the third active layer 1912, and the anode electrode 270 may serve as a storage capacitor electrode.

Referring to FIG. 9, the bank layer 290 may be disposed over the substrate 400 over which the anode electrode 270 is disposed.

In one subpixel, the bank layer 290 may include an open area OP.

The open area OP may include a plurality of light emitting areas (EA1, EA2) and at least one non-light emitting area NEA1.

For example, the open area OP may overlap with a first non-light emitting area NEA1, a first light emitting area EA1, and a second light emitting area EA2.

The first non-light emitting area NEA1 and the first light emitting area EA1 may correspond to an area where the anode electrode 270 does not overlap with the fourth insulating layer 404 in the open area OP of the bank layer 290.

For example, the first non-light emitting area NEA1 may be an area corresponding to a flat portion of the depressed portion CNC of the fourth insulating layer 404.

A portion of the first light emitting area EA1 may correspond to an inclined portion of the depressed portion CNC of the fourth insulating layer 404.

Another portion of the first light emitting area EA1 may be an area not overlapping with the anode electrode 270 in the remaining area except for the depressed portion of the fourth insulating layer 404.

The second light emitting area EA2 may correspond to an area where the anode electrode 270 overlaps with the fourth insulating layer 404 in the open area OP of the bank layer 290.

Referring to FIG. 9, an emission layer 492 and a cathode electrode 493 of a light emitting element may be sequentially disposed over the substrate 400 over which the bank layer 290 is disposed.

Referring to FIG. 9, each of the emission layer 492 and the cathode electrode 493 may have at least two step portions in an area corresponding to the open area OP of the bank layer 290.

Referring to FIG. 9, due to the step portions of the cathode electrode 493 including a reflective electrode, light emitted from the emission layer disposed between the anode electrode 270 and the cathode electrode 493 may be reflected by the step portions of the cathode electrode 493 and redirected toward the substrate 400, and thereafter, reach and exit the substrate 400.

Through this structural feature, a situation where light travels from one subpixel to another adjacent subpixel may be reduced. Thereby, the display device 100 or the display panel 110 may provide advantages of preventing such a light leakage situation and improving light extraction efficiency.

The example aspects and aspects described above will be briefly described as follows.

According to the example aspects described herein, a display device may be provided that includes a substrate on which a plurality of subpixels are disposed, an insulating layer disposed over the substrate and including at least one depressed portion in at least one subpixel among the plurality of subpixels, a first electrode disposed on the insulating layer, disposed in an area other than the at least one depressed portion, and including at least one trunk portion and at least one branch portion connected to the at least one trunk portion, a bank layer disposed on at least a portion of an upper surface of the first electrode and the insulating layer and including an open area in each of the plurality of subpixels, an emission layer disposed in the open area, and a second electrode disposed on the emission layer.

In one or more aspects, the at least one trunk portion may have a zigzag shape.

In one or more aspects, the first electrode may include a first trunk portion and a second trunk portion disposed adjacent to the first trunk portion, and at least one first branch portion connected to the first trunk portion and at least one second branch portion connected to the second trunk portion may be disposed alternately.

In one or more aspects, each of the at least one branch portion may include a head portion and a filler portion connecting the head portion and a corresponding one of the at least one trunk portion. For example, a width of the head portion may be greater than a width of the filler portion.

In one or more aspects, the head portion may have a regular hexagonal shape.

In one or more aspects, each of the emission layer and the second electrode may overlap with the first electrode and the depressed portion in the open area and include at least one step portion in the open area.

In one or more aspects, each of the emission layer and the second electrode may overlap with the first electrode and the depressed portion in the open area and include a lowered portion with a round shape in the open area.

In one or more aspects, the at least one subpixel may include at least one light emitting area and at least one non-light emitting area in an area overlapping with the open area.

According to the example aspects described herein, a display device may be provided that includes a first non-light emitting area including a first groove and a second groove, the first groove and the second groove being alternately disposed in at least a portion of the first non-light emitting area, a first light emitting area surrounding the first non-light emitting area, a second light emitting area surrounding the first light emitting area, and a second non-light emitting area comprising the second light emitting area.

In one or more aspects, an area of the first groove may be equal to an area of the second groove.

In one or more aspects, each of the first groove and the second groove may include a chamber portion and a passage portion connecting the chamber portion with an area other than the first groove and the second groove. For example, a width of the chamber portion may be greater than a width of the passage portion.

In one or more aspects, the chamber portion may have a regular hexagonal shape.

The above description has been presented to enable any person skilled in the art to make, use and practice the technical features of the present disclosure, and has been provided in the context of a particular application and its requirements as examples. Various modifications, additions and substitutions to the described aspects will be readily apparent to those skilled in the art, and the principles described herein may be applied to other aspects and applications without departing from the scope of the present disclosure. Thus, it is intended that the present disclosure covers the modifications and variations of the aspects provided they come within the scope of the appended claims and their equivalents.

What is claimed is:

1. A display device comprising:
a substrate on which a plurality of subpixels are disposed;
an insulating layer disposed over the substrate and comprising at least one depressed portion in at least one subpixel among the plurality of subpixels;
a first electrode disposed on the insulating layer, located in an area other than the at least one depressed portion, and comprising at least one trunk portion and at least one branch portion connected to the at least one trunk portion;
a bank layer located on at least a portion of an upper surface of the first electrode and the insulating layer and comprising an open area in each of the plurality of subpixels;
an emission layer disposed in the open area; and
a second electrode disposed on the emission layer.

2. The display device of claim 1, wherein the at least one trunk portion is configured in a zigzag shape.

3. The display device of claim 1, wherein the first electrode comprises a first trunk portion and a second trunk portion disposed adjacent to the first trunk portion, and at least one first branch portion connected to the first trunk portion and at least one second branch portion connected to the second trunk portion are disposed alternately.

4. The display device of claim 1, wherein each of the at least one branch portion comprises a head portion and a filler portion connecting the head portion and a corresponding one of the at least one trunk portion, and a width of the head portion is greater than a width of the filler portion.

5. The display device of claim 4, wherein the head portion has a regular hexagonal shape.

6. The display device of claim 1, wherein each of the emission layer and the second electrode overlaps with the first electrode and the at least one depressed portion in the open area and comprises a step portion in the open area.

7. The display device of claim 1, wherein each of the emission layer and the second electrode overlaps with the first electrode and the at least one depressed portion in the open area and comprises a lowered portion with a round shape in the open area.

8. The display device of claim 1, wherein the at least one subpixel comprises at least one light emitting area and at least one non-light emitting area in an area overlapping with the open area.

9. A display device comprising:
a first non-light emitting area comprising a first groove and a second groove, wherein the first groove and the second groove are alternately disposed in at least a portion of the first non-light emitting area;
a first light emitting area surrounding the first non-light emitting area;
a second light emitting area surrounding the first light emitting area; and
a second non-light emitting area surrounding the second light emitting area.

10. The display device of claim 9, wherein an area of the first groove is equal to an area of the second groove.

11. The display device of claim 9, wherein each of the first groove and the second groove comprises a chamber portion and a passage portion connecting the chamber portion with an area other than the first groove and the second groove, and a width of the chamber portion is greater than a width of the passage portion.

12. The display device of claim 11, wherein the chamber portion has a regular hexagonal shape.

13. A display device comprising:
a substrate;
an insulating layer on the substrate;
a first electrode on the insulating layer;
a bank layer on the first electrode and comprising an open area;
an emission layer on the bank layer, and
a second electrode on the emission layer,
wherein the insulating layer comprises at least one depressed portion in the open area,
wherein the first electrode is disposed on the insulating layer in an area other than the at least one depressed portion, and
wherein the emission layer is disposed on the first electrode and the at least one depressed portion in the open area.

14. The display device of claim 13, wherein the first electrode comprises at least one trunk portion and at least one branch portion connected to the at least one trunk portion.

15. The display device of claim 14, wherein the at least one trunk portion is configured in a zigzag shape.

16. The display device of claim 14, wherein each of the at least one branch portion comprises a head portion and a filler portion connecting the head portion and a corresponding one of the at least one trunk portion, and a width of the head portion is greater than a width of the filler portion.

17. The display device of claim 13, wherein the second electrode in the open area comprises a step portion.
